(19) United States
(12) Patent Application Publication
(10) Pub. No.: US 2010/0186399 A1
(43) Pub. Date: Jul. 29, 2010

(54) Thermoelectric facility comprising a thermoelectric generator and means for limiting the temperature on the generator

(76) Inventor: Simon Hüttinger, Erlangen (DE)

Correspondence Address: STAAS & HALSEY LLP, SUITE 700, 1201 NEW YORK AVENUE, N.W., WASHINGTON, DC, 20005, US

(21) Appl. No.: 12/310,629

(22) PCT Filed: Aug. 21, 2007
(86) PCT No.: PCT/EP2007/058677

§ 371 Date: Mar. 2, 2009

(30) Foreign Application Priority Data
Aug. 31, 2006 (DE) 10 2006 040 853.5

(51) Int. Cl. F01N 5/02; H01L 35/30; F01P 1/06

(52) U.S. Cl. 60/320; 136/205; 123/41.31

(57) ABSTRACT

The thermoelectric facility contains a thermoelectric generator which is thermally connected on a first side to a heat source and on a second side to a heat sink. The thermoelectric facility also has a structure for limiting the temperature on the thermoelectric generator. The structure includes a first compartment, filled with a first working medium that can melt, which compartment is connected across a large surface thereof to the heat source or to a second compartment that is filled with an evaporable second working medium. The second compartment is connected to the thermoelectric generator on its side facing away from the first compartment. The working media have a predetermined melting point or boiling point in order to prevent permanent damages to the thermoelectric generator. The thermoelectric facility is especially useful for motor vehicles that are operated by an internal combustion engine.

The invention relates to a thermoelectrical device
a) having a thermoelectrical generator, a heat source and a heat sink, wherein the thermoelectrical generator is thermally connected on a first side to the heat source and on a second side to the heat sink,
   and
b) having means for temperature limiting on the thermoelectrical generator, which means comprise a first flat chamber, having opposite surfaces, whose dimensions are matched to those of the thermoelectrical generator,
   wherein the first chamber is at least largely filled with a meltable first working medium which has a melting temperature T_{L} which is below a critical temperature above which the thermoelectrical generator is permanently damaged.

One such thermoelectrical generator is disclosed in EP 1 522 685 A1.

Heat can be converted directly to electrical energy using a so-called thermoelectrical generator. A thermoelectrical generator is a component composed of two different materials which are connected to one another, preferably two different or differently doped semiconductors, which produces an electrical voltage on the basis of the Seebeck effect when the junction points of the different materials are at different temperatures.

The Seebeck effect describes the creation of an electrical voltage in an electrical conductor along a temperature gradient, caused by thermodiffusion flows. In order to allow technical use to be made of the Seebeck effect, it is necessary to bring two different electrical conductors with different electronic heat capacities into contact with one another. As a result of the different electronic heat capacities, the electrons in the two conductors have different energies of motion at the same temperature. If these conductors are brought into contact with one another, then a diffusion flow of relatively high-energy electrons will take place in the direction of the conductor with the relatively low-energy electrons until this results in a dynamic equilibrium. If these two different conductors are denoted A and B and are brought into contact in the sequence A-B-A and, furthermore, if the junction A-B is at a temperature T₁ and the junction B-A is at a temperature T₂, then the resultant voltage is dependent only on the difference between the temperatures T₁ and T₂ and the respective Seebeck coefficients of the two conductors A and B. In consequence, a voltage which can be tapped off on a thermoelectrical generator is dependent only on the temperature difference applied to the thermal generator and on the Seebeck coefficients of the materials used.

In principle, a thermoelectrical generator can be constructed analogously to a Peltier element. Identical or similar materials as for the production of Peltier elements, for example bismuth-tellurite or silicon-germanium, can also be used for a thermoelectrical generator.

The use of semiconductor materials allows the efficiency of a thermoelectrical generator for the conversion of thermal energy to electrical energy to rise by up to several percent. Thermoelectrical generators have recently been increasingly used for exhaust-gas waste heat, for example in the case of motor vehicles, cogeneration units, or refuse incineration installations.

DE 33 14 166 A1 discloses a high-efficiency thermoelectrical system. Starting with a hot fluid flow, for example an exhaust-gas flow, thermally conductive tubes which are provided with ribs for better thermal linking are heated at one end. The thermally conductive tubes which have been heated by the fluid flow conduct the heat to the thermoelectrical generators which are mounted at the opposite end of the thermally conductive tubes, and act as heat sinks. The thermally conductive tubes are filled with an operating fluid in order to improve their thermal conductivity, which operating fluid is vaporized on the hot part of the thermally conductive tubes and recondenses on the somewhat cooler part, on which the thermoelectrical generators are arranged. The thermoelectrical system disclosed in DE 33 14 166 A1 can be used to achieve particularly effective thermal coupling of thermoelectrical generators, for example to an exhaust-gas flow. The disclosed system is particularly suitable for use in the high-temperature range at working temperatures of more than 400° C.

U.S. Pat. No. 4,125,122 A discloses a method and an apparatus for thermoelectrical conversion of heat to electrical energy. The disclosed apparatus is designed as a heat exchanger which operates on the opposing-flow principle. The apparatus which is disclosed in U.S. Pat. No. 4,125,122 A provides two mutually separate circuits in which media circulate for heat transmission. A first medium transports heat from a heat source to a heat sink. At least one first thermally conductive tube makes thermal contact with the hot flow of the first medium; at least one second thermally conductive tube makes thermal contact with the cooler flow of the first medium. Thermoelectrical generators are located in thermal contact both with one of the hot thermally conductive tubes and with one of the cooler thermally conductive tubes. A second medium circulates within the thermally conductive tubes, in a second circuit, driven by a thermosyphon effect. In that thermally conductive tube which is in thermal contact with the hot flow of the first medium, the second medium which is located within the thermally conductive tube circulates in gaseous form from a hot end, which is in thermal contact with the first medium, of the thermally conductive tube to a cooler end, which is in thermal contact with the thermoelectrical generator. At this end, which is in thermal contact with the thermoelectrical generator, the gaseous second medium condenses and in this way emits the heat condensation to the thermoelectrical generator. The second medium passes back in the liquid phase to the first end of the thermally conductive tube, in order to be vaporized once again.

The second medium circulates in the thermally conductive tube which is in thermal contact with the cold side of the thermoelectrical generator, is vaporized at the end of the thermally conductive tube which is in thermal contact with the cold side of the thermoelectrical generator, and condenses on the (even) colder side of the thermally conductive tube which in contact with the first medium.

Both the thermoelectrical system which is disclosed in DE 33 14 166 A1 and that disclosed in U.S. Pat. No. 4,125,122 A have the aim of thermal coupling of the thermoelectrical generators to a hot operating fluid in a manner which is as effective and free of losses as possible. However, in these systems, there is a risk of their thermoelectrical generators being subjected to excessively high temperatures, and they can therefore be damaged.

A further thermoelectrical device having a thermoelectrical generator and means for temperature limiting on the generator is disclosed in U.S. Pat. No. 3,881,962. In this device, a chamber-like pipeline system is provided and is filled with a working medium which can be vaporized, and the pipeline system runs between a heating area, which can be regarded as a heat source, and a condenser, which can be regarded as a heat sink. In order

to provide temperature limiting, in order to reduce damage, on a thermoelectrical module, this module is arranged
physically separated from the condenser. Furthermore, a pipeline is additionally connected to the condenser area and leads to a geodetically higher pressure valve by means of which the pressure of the working medium and thus the thermal flow from the heating area to the condenser can be limited. Temperature limiting such as this on the thermoelectrical module is physically complex.

A further thermoelectrical device having two thermoelectrical generators, a heat source and a heat sink is also disclosed in JP 2003-219 671 A. Two working media with different boiling temperatures are used.

Two operating media are also used in an energy recovery system having a thermoelectrical generator for hybrid cars, as disclosed in WO 2004/092662 A1. One of the working media is in this case used to cool a heat sink while the other working medium is connected to a heat source in the car.

EP 1 615 274 A2 discloses a thermoelectrical conversion module for energy recovery, in which a temperature difference is likewise used. In this case, thermoelectrical semiconductor elements and electrodes are arranged between a cold plate and a hot plate.

JP 2000-35824 A discloses a thermoelectrical generator for an internal combustion engine in a motor vehicle, in which temperature limiting is carried out on the thermoelectrical generator using a deformable bimetallic-strip element.

WO 80/01438 discloses a thermoelectrical generator in which two different materials with thermoelectrical characteristics are used.

The system which is disclosed in the initially cited EP 1 522 685 A1 for exhaust-gas monitoring of an automobile having a thermoelectrical generator and a means for temperature limiting has the features mentioned initially. In this case, different working media such as oil may be used to transport heat from an exhaust-gas system as heat source to the thermoelectrical generator. A thermal contact surface which can be varied with the temperature conditions to the thermoelectrical generator, in particular using a meltable solder material, leads to temperature limiting on the generator.

One object of the present invention is to specify a thermoelectrical device having the features mentioned initially, which allows good matching to the respective temperature conditions such that the risk of unacceptable overheating that has been mentioned then does not exist.

This object is achieved by the measures specified in claim 1. The invention is in this case based on the idea of using the latent heat of a phase change for protection of a thermoelectrical generator against overheating. One aim according to the invention is to specify a thermoelectrical device having a thermoelectrical generator should be specified which is thermally connected on a first side to a heat source and on a second side to a heat sink. The thermoelectrical device is furthermore intended to have means for temperature limiting on the thermoelectrical generator, which means have a flat first chamber having mutually opposite surfaces, whose dimensions are matched to those of the thermoelectrical generator and which is at least largely filled with a meltable first working medium and is thermally connected over a large area on its mutually opposite surfaces to the heat source and to the thermoelectrical generator. The first working medium is intended to have a melting temperature which is below a critical temperature above which the thermoelectrical generator is permanently damaged. The

advantages associated with this refinement of the thermoelectrical device are, in particular, that the thermoelectrical generator is protected against thermal destruction when the temperature of the heat source rises. If the heat source reaches the melting temperature of the first working medium, thermal energy is used for melting the first working medium. Furthermore, advantageously, when the temperature of the heat source subsequently falls, the latent heat fusion can once again be emitted to the thermoelectrical generator. This allows the thermoelectrical generator to be kept at a temperature which is defined by the melting temperature of the first working medium. Temperature fluctuations of the heat source can be coped with provided that the storage capacity of the meltable first working medium is sufficient.

The means for temperature limiting should, according to the invention, also have a flat second chamber which has mutually opposite surfaces and whose dimensions are matched to those of the thermoelectrical generator, which second chamber is at least largely filled with a second working medium, which can be vaporized, and is connected over a large area on its mutually opposite surfaces to the first chamber and to the thermoelectrical generator. Furthermore, the means for temperature limiting may have a pipeline system which is connected to the second chamber and in which a recooler is integrated which is located at a geodetically higher point than the second chamber and the pipeline system can be designed such that a gaseous component of the second working medium can rise without any impediment from the second chamber to the recooler, where it can be reliquefied. Furthermore, the means for temperature limiting may be designed such that liquid and gaseous second working medium can recirculate at least in parts of the second chamber and of the pipeline system as a result of a thermosyphon effect. The second working medium may furthermore

have a boiling temperature which is above the melting temperature of the first medium and is below the critical temperature above which the thermoelectrical generator is permanently damaged. If the temperature of the heat source rises above the melting point of the first medium, thermal energy is first of all stored, by virtue of the latent heat of the melting process, in the first chamber, which is filled with a meltable first working medium. If the temperature of the heat source rises further, or remains at a temperature level which is above the melting temperature of the first medium, and the storage capacity of the first working medium is exhausted, the second working medium starts to change to the gaseous state on reaching its boiling temperature. As a result of the “liquid-tight” phase transition of the second working medium, thermal energy is absorbed by the second working medium. Gaseous second working medium can rise to a recooler where it is liquefied again. Excess heat is dissipated in this way via the recooler. The thermoelectrical device therefore on the one hand has a heat store and on the other hand has a device for limiting the maximum temperature that can occur at the thermoelectrical generator to the boiling point of the second working medium. In this way, it is not only possible to buffer temperature fluctuations of the heat source by melting and recrystallization of the first working medium, but also protect the thermoelectrical generator against overheating.

Advantageous refinements of the thermoelectrical device according to the invention are specified in the claims which are dependent on claim 1. In this case, the embodiment according to this claim can be combined with the features of one of the dependent claims, or preferably also with those of a plurality of dependent claims. Accordingly, the thermoelectrical device according to the invention may also additionally have the following features:
the first working medium may have a lower thermal conductivity in the liquid state than in the solid
state. Every physical component has a specific thermal resistance associated with it. If the thermal resistance of the liquid phase of a material is higher than the thermal resistance of the solid phase, then the thermal resistance of the corresponding material rises when the melting temperature is exceeded. If a material such as this is used as the first working medium in a thermoelectrical device, then additional protection can be achieved for the thermoelectrical generator against overheating.
The second working medium may have a melting temperature which corresponds essentially to a preferred operating temperature of the thermoelectrical generator, wherein the operating temperature is below the critical temperature above which the thermoelectrical generator is damaged. The thermoelectrical generator can therefore be kept at an optimum operating temperature, in a particularly advantageous manner. This allows temperature fluctuations of the heat source to be buffered.
The heat source may be thermally connected at least to parts of an exhaust-gas system of an internal combustion engine, or may be formed by at least parts of the exhaust-gas system. The exhaust-gas heat of an internal combustion engine such as this may be made useful by using a thermoelectrical generator which is thermally connected to the exhaust-gas system of an internal combustion engine.
The heat sink may be thermally connected at least to parts of a cooling system of an internal combustion engine, or may be formed by at least parts of the cooling system. A heat source and a heat sink are required for operation of a thermoelectrical generator. An internal combustion engine typically has a cooling system and in this way allows a heat sink to be provided for the thermoelectrical generator
in a simple and effective manner.
The heat sink may be thermally connected to a surface to be cooled by an air flow. A surface to be cooled by an air flow represents a particularly simple, robust and low-cost component, which can be used as a heat sink.
The internal combustion engine may be part of a motor vehicle. Modern motor vehicles require increasing amounts of electrical power in order to operate various electronic devices. The use of the exhaust-gas heat of the internal combustion engine of the motor vehicle reduces the primary power requirement of the motor vehicle for covering the required electrical power.
The first working medium may be a solder which, in particular, contains lead, tellurium or bismuth in elementary form, or as an alloy partner. A solder which contains one or more of the abovementioned elements provides the physical characteristics desired for the first working medium and has also been tested in technical applications.
The second working medium may be an oil, preferably an engine oil, having a boiling temperature between 100° C. and 500° C., preferably having a boiling temperature between 200° C. and 300° C., at a pressure between 2 and 5 bar. The stated temperature ranges are particularly suitable for operation of a thermoelectrical generator. The cooling water in a cooling system of an internal combustion engine typically has a maximum temperature of about 100° C. In order at the same time to ensure an effective energy yield as a result of the temperature difference applied to the thermoelectrical generator, the hot side of the thermoelectrical generator should be at a temperature of more than about 200° C. The maximum load capacity of thermoelectrical generators
which are widely commercially available is about 300° C. Thermoelectrical generators which are designed specifically for high-temperature applications have maximum load temperatures of about 500° C. Since the boiling temperature of the second working medium defines the maximum of the mean temperature which is permissible for temperature limiting, a boiling point in the stated temperature ranges for a thermoelectrical device is particularly advantageous.

Further advantageous refinements of the thermoelectrical device according to the invention having means for temperature limiting will become evident from the claims that have not been mentioned above and in particular from the drawing, which will be explained in the following text, in which preferred refinements of the thermoelectrical device according to, the invention are indicated. In this case, in the figures:

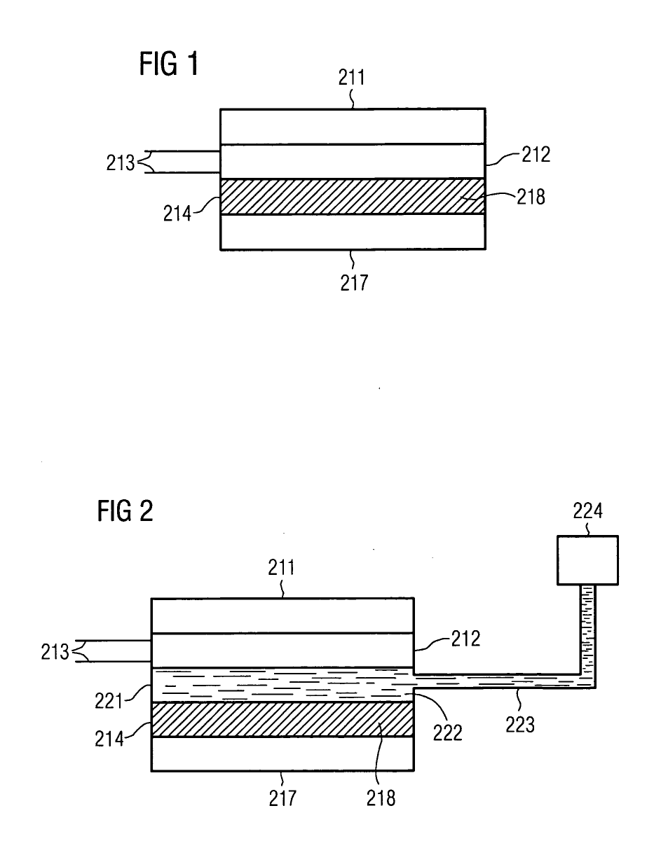

FIG. 1 shows the schematic design of a thermoelectrical device having means for temperature limiting,

FIG. 2 shows the schematic design of a thermoelectrical device in which a second chamber, which is filled with a second liquid working medium, has been added to the means for temperature limiting,

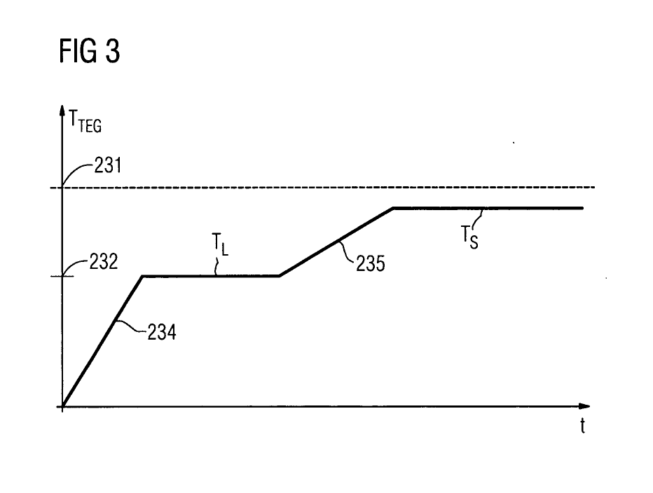

FIG. 3 shows the schematic profile of the temperature of the thermoelectrical generator of a thermoelectrical device as a function of time,

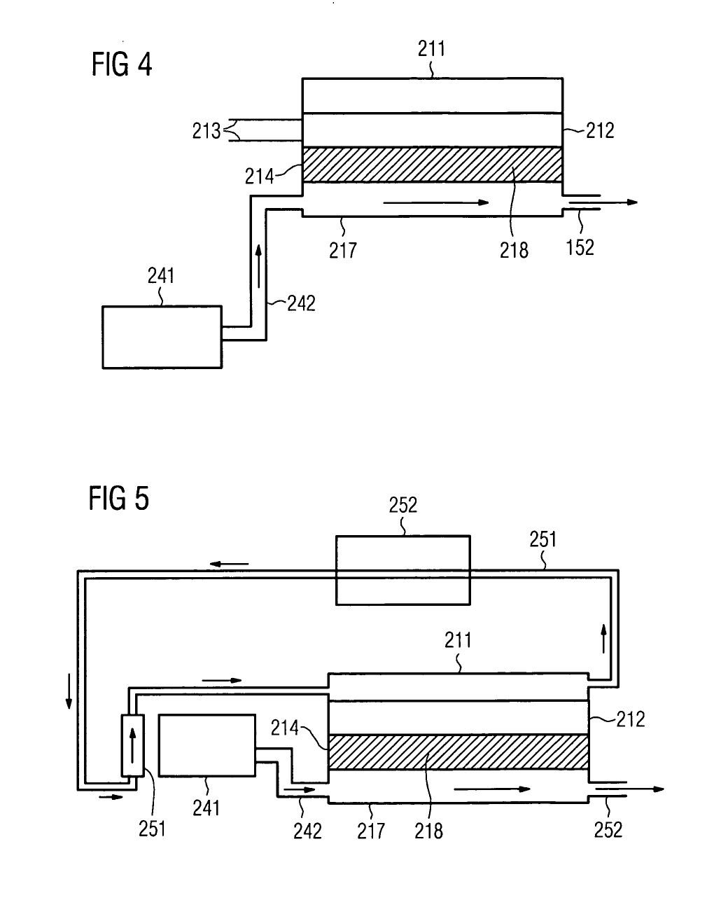

FIG. 4 shows the schematic design of a thermoelectrical device in which the heat source is connected to parts of the exhaust-gas system of an internal combustion engine, and

FIG. 5 shows the schematic design of a thermoelectrical device in which the heat source is connected to parts of an exhaust-gas system, and the heat sink is connected to parts of the cooling system of an internal combustion engine.

Mutually corresponding parts in the figures are in each case provided with the same reference symbols. Parts which are not shown in more detail are generally known.

FIG. 1 shows the schematic design of a thermoelectrical device according to one preferred exemplary embodiment. Its thermoelectrical generator 212 is thermally connected over a large area on a first face to a heat sink 211. The warm face of the thermoelectrical generator 212 is thermally connected over a large area to a chamber 214 which is filled with a meltable first working medium 218. The first chamber 214 is once again thermally connected over a large area to a heat source 217. The thermal connection between the abovementioned elements can preferably be provided by a mechanical connection, likewise over a large area.

The heat source 217 and the heat sink 211 result in a temperature gradient across the thermoelectrical generator 212. An electrical voltage can be tapped off at electrical connections 213 of the thermoelectrical generator 212.

In order to explain the method of operation of the thermoelectrical device according to the preferred exemplary embodiment illustrated in FIG. 1, it will be assumed that the heat source is at a temperature which fluctuates over time above a value which is suitable for operation of the thermoelectrical generator.

If the temperature of the heat source rises above the melting temperature T_{L} of the first working medium 218, then this first working medium 218 is at least partially melted. The temperature of the thermoelectrical generator 212 in this case remains constant. If the temperature of the heat source 217 then falls below the melting temperature of the first working medium 218, then the liquid first working medium 218 will be solidified again. The latent heat of solidification is in this case at least partially

emitted to the thermoelectrical generator 212. This makes it possible to maintain a constant temperature gradient across the thermoelectrical generator.

FIG. 2 shows the design, which is known per se from FIG. 1, of a thermoelectrical device according to a further preferred exemplary embodiment. The means for temperature limiting have in this case had a further chamber 221, filled with a liquid 222, added to them. A pipeline system 223 in which a recooler 224 is integrated, is connected to this chamber. The second chamber 221 and the pipe system 223 are preferably designed such that any gaseous second working medium 222 which occurs can rise without any impediment to the recooler 224, which is located at a geodetically higher position than the second chamber 221. The gaseous component of the second working medium 222 can be liquefied again in the recooler 224 and can be passed back into the second chamber 221, driven by the force of gravity. Gaseous and liquid second working medium 222 can circulate at least in parts of the second chamber 221 and of the pipeline system 223 as a result of a thermosyphon effect.

The rest of the method of operation of the exemplary embodiments of the thermoelectrical device illustrated in FIG. 2 will be explained in the following text with reference to the graphs which are illustrated schematically in FIG. 3.

FIG. 3 shows a schematic temperature profile of the temperature of the thermoelectrical generator T_{TEG} as a function of the time t. This assumes a thermoelectrical device according to the preferred exemplary embodiment illustrated in FIG. 2. The explanation of the method of operation will be based on a heat source which is at a constant high temperature which is above the maximum permissible temperature 231 for the thermoelectrical generator 212. First of all, the temperature of the thermoelectrical generator T_{TEG} rises at a certain heating rate according to the part of the graph annotated 234. On reaching the melting temperature T_{L} of the

first medium, the heat which originates from the heat source is used to melt the first medium 218, which is located in the first chamber 214. The melting temperature T_{L} of the first medium can preferably correspond to a preferred operating temperature 232 of the thermoelectrical generator 212.

Once all of the first medium 212 has changed to the liquid phase, the temperature of the thermoelectrical generator T_{TEG} rises according to a further part of the graph, which is annotated 235. The gradient of the temperature rise in the part annotated 235 may, in particular, be less than the gradient of the part of the graph annotated 234. The decrease in the rate of temperature rise is a result of the thermal conductivity of the liquid phase of the first medium 218 being less than that of the solid phase.

The use of a medium such as this, in which the liquid phase has a lower thermal conductivity than the solid phase allows the thermal resistance of the chamber 214, once the medium 218 has melted completely, to be increased in a particularly advantageous manner, thus ensuring additional thermal protection for the thermoelectrical generator 212.

As the temperature increases further, the temperature of the thermoelectrical generator T_{TEG} rises further to the boiling temperature Tₛ of the second medium 222. On reaching the boiling temperature Tₛ of the second medium 222, this medium changes to the gaseous phase. Gaseous second medium 222 can rise without any impediment through the pipeline system 223 to the recooler 224, where it can be liquefied again. In this way, excess heat which would otherwise contribute to thermal loading on the thermoelectrical generator 212, can be dissipated via the recooler 224.

According to the described preferred exemplary embodiment of the thermoelectrical device, it is not possible, as illustrated in FIG. 3, for the maximum temperature T_{TEG} across the thermoelectrical generator 212 to reach a critical value 231 beyond which the thermoelectrical generator 212 could be destroyed.

FIG. 4 shows a further preferred exemplary embodiment of a thermoelectrical device. The design, which is known per se from FIG. 1, has been extended such that, in this case, the heat source 217 is connected to parts of the exhaust-gas system 242 of an internal combustion engine 241. The connection of the heat source 217 to the exhaust-gas system 242 of the internal combustion engine 241 is particularly advantageous since, typically, the exhaust gas of an internal combustion engine 241 may be at different temperatures, depending on the load level of the internal combustion engine 241. The temperature-moderating effect of the first medium 218 in the first chamber 214 can be particularly advantageous in conjunction with an internal combustion engine.

FIG. 5 shows a further preferred exemplary embodiment of a thermoelectrical device in which the device that is known per se from FIG. 4 has been extended such that the heat sink 211 is connected to parts of the recooling system 251 of an internal combustion engine 241. An internal combustion engine 241 typically has a cooling system 251. This cooling system, which is normally operated with water, and whose temperature is about 100° C. represents a suitable, widely available, heat sink 211 for operation of a thermoelectrical generator 212. Furthermore, the heat sink can be connected to at least parts of the oil cooling system of the internal combustion engine 241. Additionally or else exclusively, the heat sink 211 can be thermally connected to a surface 252 to be cooled by an air flow.

According to a further exemplary embodiment, which will not be described in any more detail, the thermoelectrical device can be used in a

motor vehicle with an internal combustion engine 241. A surface 252 to be cooled by an air flow may in this case be cooled, for example, by the wind of motion of the motor vehicle when it is being operated.

1-11. (canceled)

12. A thermoelectrical device comprising:
a thermoelectrical generator having first and second sides;
a heat source thermally connected to the first side of the thermoelectrical generator;
a heat sink thermally connected to the second side of the thermoelectrical generator; and
a temperature limiting structure comprising:
a first chamber having substantially flat and first and second mutually opposite surfaces whose dimensions are substantially matched to those of the thermoelectrical generator, the first chamber containing a meltable first working medium having a melting temperature which is below a critical temperature above which the thermoelectrical generator is permanently damaged, the first chamber being connected by the first mutually opposite surface to the heat source;
a second chamber containing a second working medium which can be vaporized, the second working medium having a boiling temperature which is above the melting temperature of the first working medium and below the critical temperature, the second chamber having substantially flat and first and second mutually opposite surfaces whose dimensions are substantially matched to those of the thermoelectrical generator, the first mutually opposite surface of the second chamber being connected to the second mutually opposite surface of the first chamber, the second mutually opposite surface of the second chamber being connected to the first side of the thermoelectrical generator;
a pipeline system connected to the second chamber; and
a recooler integrated into the pipeline system, the recooler being located at a geodetically higher point than the second chamber and designed such that a gaseous component of the second working medium can rise without impediment from the second chamber to the recooler where it can be reliquefied, the second chamber and the pipeline system being designed such that a thermosyphon effect can circulate liquid and gaseous second working medium at least in parts of the second chamber and the pipeline system.

13. The thermoelectrical device as claimed in claim 12, wherein the first working medium has a lower thermal conductivity in a liquid state than in a solid state.

14. The thermoelectrical device as claimed in claim 12, wherein
the melting temperature of the first working medium which corresponds essentially to a preferred working temperature of the thermoelectrical generator, and
the preferred working temperature of the thermoelectrical generator is below the critical temperature above which the thermoelectrical generator is permanently damaged.

15. The thermoelectrical device as claimed in claim 12, wherein the heat source is thermally connected to parts of an exhaust-gas system of an internal combustion engine, or is formed by parts of the exhaust-gas system.

16. The thermoelectrical device as claimed in claim 12, wherein the heat sink is thermally connected to parts of a cooling system of an internal combustion engine, or is formed by parts of the cooling system.

17. The thermoelectrical device as claimed in claim 12, wherein the heat sink is thermally connected to a surface cooled by an air flow.

18. The thermoelectrical device as claimed in claim 12, wherein the internal combustion engine is part of a motor vehicle.

19. The thermoelectrical device as claimed in claim 12, wherein the first working medium is a solder.

20. The thermoelectrical device as claimed in claim 19, wherein the solder contains lead, tellurium or bismuth in elementary form or as an alloy partner.

21. The thermoelectrical device as claimed in claim 14, wherein the second working medium is an oil.

22. The thermoelectrical device as claimed in claim 14, wherein the second working medium is an engine oil, having a boiling temperature between 100° C. and 500° C. at a pressure between 2 and 5 bar.

23. The thermoelectrical device as claimed in claim 22, wherein the engine oil which is provided as the second working medium has a boiling temperature between 200° C. and 300° C. at a pressure between 2 bar and 5 bar.

24. The thermoelectrical device as claimed in claim 13, wherein the melting temperature of the first working medium which corresponds essentially to a preferred working temperature of the thermoelectrical generator, and the preferred working temperature of the thermoelectrical generator is below the critical temperature above which the thermoelectrical generator is permanently damaged.

25. The thermoelectrical device as claimed in claim 24, wherein the heat source is thermally connected to parts of an exhaust-gas system of an internal combustion engine, or is formed by parts of the exhaust-gas system.

26. The thermoelectrical device as claimed in claim 25, wherein the heat sink is thermally connected to parts of a cooling system of an internal combustion engine, or is formed by parts of the cooling system.

27. The thermoelectrical device as claimed in claim 26, wherein the heat sink is thermally connected to a surface cooled by an air flow.

28. The thermoelectrical device as claimed in claim 27, wherein the internal combustion engine is part of a motor vehicle.

29. The thermoelectrical device as claimed in claim 28, wherein the first working medium is a solder.

30. The thermoelectrical device as claimed in claim 29, wherein the solder contains lead, tellurium or bismuth in elementary form or as an alloy partner.

31. The thermoelectrical device as claimed in claim 30, wherein the second working medium is an engine oil, having a boiling temperature between 100° C. and 500° C. at a pressure between 2 and 5 bar.
